(19) United States
(12) Patent Application Publication
(10) Pub. No.: US 2018/0094192 A1
(43) Pub. Date: Apr. 5, 2018

(54) POLYMER NETWORKS

(71) Applicant: UNIVERSITY OF HULL, HULL, HUMBERSIDE (GB)

(72) Inventors: STEPHEN MALCOLM KELLY, HULL, HUMBERSIDE (GB); MARY O'NEILL, HULL, HUMBERSIDE (GB); STUART PAUL KITNEY, HULL, HUMBERSIDE (GB)

(73) Assignee: UNIVERSITY OF HULL, HULL, HUMBERSIDE (GB)

(21) Appl. No.: 15/559,934

(22) PCT Filed: Apr. 14, 2016
(86) PCT No.: PCT/GB2016/051039

§ 371 Date: Sep. 20, 2017

(30) Foreign Application Priority Data
Apr. 14, 2015 (GB) 1506309.2

(51) Int. Cl. C09K 19/34; C09K 11/06; H01L 51/00; H05B 33/14

(52) U.S. Cl. CPC C09K 19/3497; C09K 19/3477; C09K 11/06; H01L 51/0036; C09K 2019/0448; H01L 51/0072; H01L 51/0074; H05B 33/14; H01L 51/0068

(57) ABSTRACT

The invention provides photopolymerisable or photocrosslinkable reactive mesogen for forming a hole-transporting or light emitting polymer network, said mesogen having the structure (III) wherein M is a chromophoric aromatic or heterocyclic moiety; A₁ and A₂ are carbazole groups substituted in the 3-position of the carbazole ring, and may be the same or different; S₁ and S₂ are spacers, and may be the same or different; B₁ and B₂ are polymerisable groups, and may be the same or different; and m and n are independently integers from 1 to 10. The invention also provides a material for forming a light emitting or charge transporting polymer network comprising the photopolymerisable or photocrosslinkable reactive mesogen, a charge transporting or light emitting polymer network which is obtained by polymerisation or crosslinking of the mesogen, a process for the preparation of the polymer via photopolymerisation or photocrosslinking of suitable end-groups of the mesogen, a device comprising a polymer layer formed from the charge transporting or light emitting polymer network, a process for applying a charge transporting or light emitting polymer network to a surface and a backlight or display comprising a charge transporting or light emitting polymer network.

### FIELD OF THE INVENTION

The present invention relates to novel hole-transporting and light emitting polymers and their precursors, and the use of the polymers in organic light emitting diodes. The invention also concerns methods for the preparation of these polymers.

### BACKGROUND TO THE INVENTION

Various methods are available for the provision of flat panel displays. For example, liquid crystal displays (LCDs) and plasma systems are well known in the art. Such systems, however, typically require intense back lighting which presents a heavy drain on power. In addition, the low intrinsic brightness of LCDs is believed to be due to high losses of light caused by the absorbing polarizers and filters which can result in external transmission efficiencies of as low as 4%.

More recently, therefore, attention has focused on the use of organic light emitting diodes (OLEDs) for this purpose, such systems offering advantages over the earlier technologies in terms of high brightness, low voltage operation and low power consumption, much wider viewing angles, lower cost and improved response times. In addition, OLEDs can be produced in a light and very thin form on flexible substrates, such as plastics, via roll-to-roll processing.

There have been two main approaches to the production of OLEDs in the prior art. In the first approach, layers of small fluorescent or phosphorescent organometallic molecules and charge-transporting compounds in glassy state have been deposited on substrates by means of thermal vapour deposition in vacuum ovens, with patterning/pixilation being achieved by the use of masks or shadow masks. However, these systems had drawbacks in terms of non-scalability, so that only small displays could be produced. In addition, the requirement for the use of multiple chromophoric moieties within these systems resulted in problems with differential chromophore ageing, and the systems also suffered from fragile layers, high cost (associated with the use of batch vacuum deposition processes), and no capability for polarised emission.

Subsequently, attention focused on the use of polymer light-emitting diodes (PLEDs), comprising light-emitting and charge-transporting conjugated polymers in a glassy state which are solution deposited on a substrate by means of techniques such as inkjet printing or spin coating, or using doctor blade technology. Patterning/pixilation is effected by means of inkjet techniques with polyimide templates. Unfortunately, the use of inkjet deposition processes produces large round pixels, and the technique generally has limited multilayer capability, so that displays are often monochrome, there is no triplet emission, scalability problems arise, and polarised emission is complex and expensive.

Hence, in the light of the various disadvantages associated with these prior art systems, the present inventors investigated the use of liquid crystal organic light-emitting diode materials (LC-OLEDs) which comprised light-emitting and charge-transporting liquid crystals as polymer networks. These materials were deposited on substrates by means of solution processing using spin coating, inkjet printing, doctor blade techniques, and patterning/pixilation was achieved by means of photolithography using photo-masks.

These LC-OLED systems showed advantages over the prior art in terms of patternability, which could be achieved using standard LCD manufacturing processes and equipment, for example, by means of photolithography using UV illumination through shadow masks. The systems also had a multilayer capability, forming insoluble and intractable polymer networks, could be obtained using the above solution and low temperature processing methods of spin coating, ink-jet printing and doctor blade techniques, and were available at low cost. In addition, the systems are scalable to large-area displays, have a facility for polarised emission for LCD backlights and security applications (holography) and display high charge-carrier mobility values due to the presence of efficient charge transport layers.

Thus, in a series of patents including U.S. Pat. No. B2-6,867,243, U.S. Pat. No. B2-7,166,239, U.S. Pat. No. B2-7,199,167 and U.S. Pat. No. B2-7,265,163, the present inventors have disclosed a class of light emitting polymers which can be employed in displays which provide opportunities for systems having lower power consumption and/or higher brightness. The combination of these light emitting polymers with existing LCD technology has offered the possibility of achieving low-cost, bright, portable displays with the benefits of simple manufacturing and enhanced power efficiency.

The disclosed light emitting polymers are obtained by a polymerisation process which involves polymerisation of reactive mesogens, typically in liquid crystal form, via photopolymerisation of suitable end-groups of the mesogens. Thus, a process for the formation of a light emitting polymer is disclosed, the process comprising photopolymerisation of a reactive mesogen having the formula (I):

B-S-A-S-B (I)

wherein:
A is a chromophore;
S is a spacer; and
B is an endgroup which is susceptible to photopolymerisation.

The photopolymerisation process may be schematically represented in the following manner:

wherein:
C is a chromophore;
PG is a polymerisable group; and
S is an aliphatic spacer.

Thus, the present inventors have previously disclosed a series of materials having a linear structure wherein polymerisable end groups are separated by linear aliphatic spacers from the linear chromophoric core of the material and, whilst these materials offer acceptable performance in a number of applications, they do not address a requirement for different and enhanced levels of performance in other applications. Thus, for example, it is frequently desirable that materials have improved hole transporting and hole collecting properties, and the ability to tailor materials accordingly would be highly desirable. Furthermore, low melting point materials which are liquid crystalline at or around room temperature could lead to significantly easier methods of manufacture.

Accordingly, in GB Patent Application No. 1101094.9, the present inventors then proposed a photopolymerisable or photocrosslinkable reactive mesogen for forming a charge transporting or light emitting polymer network, the mesogen having an asymmetric structure (II):

B₁-S₁-A₁-M-(A-S-B)ₙ (II)

wherein:
A and A₁ are chromophores;
S and S₁ are spacers;
B and B₁ are end groups which are susceptible to photopolymerisation or photocrosslinking;
M is a non-chromophoric aliphatic, alicyclic or aromatic moiety; and
n is an integer from 1 to 10;
   wherein, when the value of n is greater than 1, each of the groups A, S and B may be the same or different, and M is preferably of the formula Y-Zₘ, wherein Y is an aliphatic, alicyclic or aromatic moiety, Z is an aliphatic linking group and m is an integer from 2 to 4, and wherein each of the Z groups may be the same or different.

GB Patent Application No. 1101094.9 also envisaged materials for forming a charge transporting or light emitting polymer network which comprise at least one photopolymerisable or photocrosslinkable reactive mesogen having the structure (II) and optionally also comprising at least one additional photopolymerisable or photocrosslinkable reactive mesogen of formula (I):

B-S-A-S-B (I)

wherein:
A is a chromophore;
S is a spacer; and
B is an endgroup which is susceptible to photopolymerisation or photocrosslinking.

This disclosure also provided charge transporting or light emitting polymer networks obtained by polymerisation or crosslinking of said materials, processes for the preparation of said polymer networks via the photopolymerisation or photocrosslinking of end-groups of the mesogen, devices comprising layers formed from either said materials or said polymers, processes for applying charge transporting and/or light emitting polymers to a surface, and backlight or displays comprising at least one said material or at least one said polymer network.

Despite these developments, however, it was still apparent that the known materials were incapable of providing the required standard of performance in terms of energy levels, due to the tendency of organic materials to form deep lying HOMO (Highest Occupied Molecular Orbital) compounds, thereby making them unsuitable as HT (hole-transporting) materials. Different chemical moieties would therefore be required which satisfied these criteria whilst also optimally retaining liquid crystallinity and polymerisability, in addition to providing the required physical properties. It is these requirements that the present invention seeks to address.

### SUMMARY OF THE INVENTION

Thus, according to a first aspect of the present invention, there is provided a photopolymerisable or photocrosslinkable reactive mesogen for forming a hole-transporting or light emitting polymer network, said mesogen having the structure (III):

(B₁-S₁-A₁)ₙ-M-(A₂-S₂-B₂)ₘ (III)

wherein:
M is a chromophoric aromatic or heterocyclic moiety;
A₁ and A₂ are carbazole groups substituted in the 3-position of the carbazole ring, and may be the same or different;
S₁ and S₂ are spacers, and may be the same or different;
B₁ and B₂ are polymerisable groups, and may be the same or different; and
m and n are independently integers from 1 to 10.

Preferably, m and n independently have values of from 1 to 3.

Polymerisable groups B₁ and B₂ are attached via the spacer groups to the nitrogen atom of the carbazole group. In preferred embodiments of the invention, B₁ and B₂ are photopolymerisable or photocrosslinkable groups.

Preferably, M is an aromatic or heterocyclic moiety having sufficient length to provide liquid crystallinity in view of a high length to breadth ratio. Typically, therefore, M is a chromophoric aromatic or heterocyclic moiety comprising at least four aromatic, fused aromatic, or heterocyclic rings.

According to a second aspect of the invention, there is provided a material for forming a charge transporting or light emitting polymer network, said material comprising at least one photopolymerisable or photocrosslinkable reactive mesogen, said mesogen having the structure (III):

(B₁-S₁-A₁)ₙ-M-(A₂-S₂-B₂)ₘ (III)

wherein A₁, A₂, S₁, S₂, B₁, B₂, M, m and n are as hereinbefore defined.

Optionally, said material according to the second aspect of the invention comprises at least one additional photopolymerisable or photocrosslinkable reactive mesogen which, in a preferred embodiment may have the formula (I):

B-S-A-S-B (I)

wherein:
A is a chromophore;
S is a spacer; and
B is an endgroup which is susceptible to photopolymerisation or photocrosslinking.

According to a third aspect of the present invention, there is provided a charge transporting or light emitting polymer network which is obtained by polymerisation or crosslinking of a material according to the second aspect of the invention which comprises at least one photopolymerisable or photocrosslinkable reactive mesogen according to the first aspect of the invention.

In embodiments of the third aspect of the invention wherein said light emitting or hole-transporting polymer network is obtained by polymerisation or crosslinking of a composition additionally comprising at least one additional photopolymerisable or photocrosslinkable reactive mesogen, said at least one additional photopolymerisable or photocrosslinkable mesogen preferably has the formula (I):

B-S-A-S-B (I)

wherein A, S and B are as hereinbefore defined.

In certain embodiments of the third aspect of the invention the charge transporting or light emitting polymer network obtained has a molecular weight of above 4,000.

According to a fourth aspect of the invention, there is provided a process for the preparation of a polymer network according to the third aspect of the invention from a material according to the second aspect of the invention, said process comprising the polymerisation or crosslinking of said material comprising at least one reactive mesogen via photopolymerisation or photocrosslinking of suitable end-groups of the at least one mesogen.

More particularly, there is provided a process for forming a charge transporting or light emitting polymer network comprising photopolymerisation or photocrosslinking of a composition comprising at least one reactive mesogen having the formula (III):

(B₁-S₁-A₁)ₙ-M-(A₂-S₂-B₂)ₘ (III)

wherein A₁, A₂, S₁, S₂, B₁, B₂, M, m and n are as hereinbefore defined, and wherein said process provides a hole-transporting or light emitting polymer network.

In a preferred embodiment of the fourth aspect of the invention said process for the preparation of a polymer according to the third aspect of the invention comprises the preparation of a polymer from at least one reactive mesogen according to the first aspect of the invention and at least one additional photopolymerisable or photocrosslinkable mesogen, said process comprising the polymerisation or crosslinking of said reactive mesogens via photopolymerisation or photocrosslinking of suitable end-groups of the mesogens. In a preferred embodiment, said at least one additional photopolymerisable or photocrosslinkable mesogen has the formula (I), as hereinbefore defined.

In certain embodiments of the fourth aspect of the invention the process for the preparation of a polymer network according to the third aspect of the invention comprises the preparation of a polymer network from at least one reactive mesogen according to the first aspect of the invention wherein said reactive mesogen has a molecular weight of from 400 to 2,000.

According to a fifth aspect of the present invention, there is provided a device comprising either a layer formed from at least one material according to the second aspect of the invention or a polymer layer formed from at least one polymer according to the third aspect of the invention. Typically, said device is obtained by a process according to the sixth aspect of the invention.

Thus, according to a sixth aspect of the present invention, there is provided a process for applying a hole-transporting and/or light emitting polymer to a surface, said process comprising applying a material according to the second aspect of the invention to said surface and photopolymerising or photocrosslinking said material in situ to form at least one hole-transporting or light emitting polymer network. Preferably, said material is applied to said surface, typically from solution, by means of a spin-coating technique. Preferably, said surface comprises a photoalignment layer.

According to a seventh aspect of the present invention, there is provided a backlight or display comprising at least one material according to the second aspect of the invention or at least one hole-transporting or light emitting polymer network according to the third aspect of the invention.

### BRIEF DESCRIPTION OF THE DRAWINGS

Embodiments of the invention are further described hereinafter with reference to the accompanying drawings, in which:

FIG. 1 is a reaction scheme illustrating the synthesis of a first reactive mesogen according to the invention;

FIG. 2 is a reaction scheme illustrating the synthesis of a second reactive mesogen according to the invention;

FIG. 3 is a reaction scheme illustrating the synthesis of a third reactive mesogen according to the invention; and

FIG. 4 is a reaction scheme illustrating the synthesis of a fourth reactive mesogen according to the invention.

FIG. 5 is a reaction scheme illustrating the synthesis of a fifth reactive mesogen according to the invention.

### DETAILED DESCRIPTION OF THE INVENTION

The present inventors have provided photopolymerisable or photocrosslinkable reactive mesogens for use in the formation of hole-transporting or light emitting polymer networks, said mesogens having the structure (III):

(B₁-S₁-A₁)ₙ-M-(A₂-S₂-B₂)ₘ (III)

wherein:
M is a chromophoric aromatic or heterocyclic moiety;
A₁ and A₂ are carbazole groups substituted in the 3-position of the carbazole ring, and may be the same or different;
S₁ and S₂ are spacers, and may be the same or different;
B₁ and B₂ are polymerisable groups, and may be the same or different; and
m and n are independently integers from 1 to 10.

In certain embodiments, M is a chromophoric aromatic or heterocyclic moiety comprising two or more aromatic, fused aromatic, or heterocyclic rings. In some embodiments, M is a chromophoric aromatic or heterocyclic moiety comprising at least three aromatic, fused aromatic, or heterocyclic rings.

In typical embodiments, M is an aromatic or heterocyclic moiety having sufficient length to provide liquid crystallinity in view of a high length to breadth ratio. Typically, M is a chromophoric aromatic or heterocyclic moiety comprising at least four aromatic, fused aromatic, or heterocyclic rings.

Most suitably, m and n independently have values of from 1 to 3.

Polymerisable groups B₁ and B₂ are respectively attached via the spacer groups S₁ and S₂ to the nitrogen atom of the carbazole group. In preferred embodiments of the invention, B₁ and B₂ are photopolymerisable or photocrosslinkable groups.

In certain embodiments, the carbazole groups comprise N-substituted carbazole groups. Typical N-substituents include alkyl or aryl groups which may themselves be unsubstituted or substituted with substituents which may, for example, be selected from the group consisting of: hydroxy, carboxy, carboxamido, imino, alkanoyl, cyano, cyanomethyl, nitro, amino, halogen (e.g. fluoro, chloro or bromo), alkoxy (e.g. methoxy, ethoxy or propoxy), haloalkoxy (e.g. trifluoromethoxy), alkylcarbonyl, alkylcarboxy, C₃₋₆ cycloalkyl (e.g. cyclohexyl), aryl (e.g. phenyl), heterocyclyl, aryloxy or heterocyclyloxy. Heterocyclic rings may be saturated or unsaturated. Alkyl substituents may also be substituted with, for example, aryl-C₁₋₆ alkyl (e.g. benzyl) or C₁₋₆ alkyl aryl.

Typical substituents include C₁₋₁₀ alkyl groups which are unsubstituted or substituted with hydroxyl, alkoxy, alkylcarboxy or heterocyclyloxy groups. Particularly suitable groups include C₈₋₁₀ alkyl groups, e.g. n-octyl or n-nonyl groups which may be unsubstituted or substituted, typically at the chain end, with, for example, hydroxy groups, alkylcarboxy groups such as isopropylcarboxy, or heterocyclyloxy groups such as tetrahydropyranyloxy groups.

Useful spacer groups (S) typically comprise linear organic chains, including, for example, aliphatic, cycloaliphatic, aromatic or (saturated or unsaturated) heterocyclyl groups. The chains may be saturated or unsaturated. Aliphatic or cycloaliphatic spacers are preferred.

Favoured endgroups (B₁ and B₂) are susceptible to photopolymerisation or photocrosslinking, typically by means of a radical process using UV radiation, generally unpolarized radiation. Examples of suitable groups may include, for example, 1,4-nonconjugated dienes and acrylate and methacrylate groups.

The group M is a divalent core linking group. Suitable core linking groups comprise aromatic or heterocyclic ring systems and may, for example, be chosen from aromatic systems such as benzene, naphthalene, fluorene, anthracene or phenanthrene, or heterocyclic systems including, for example, sulphur-containing heterocycles such as thiophene, bisthiophene, dibenzothiophene or benzothiadiazole rings.

The reactive mesogen monomer typically has a molecular weight of from 400 to 2,000. Lower molecular weight monomers are preferred because their viscosity is also lower, thereby leading to enhanced spin coating characteristics and shorter annealing times, which aid processing.

The hole-transporting or light emitting polymer network according to the third aspect of the invention typically has a molecular weight of above 4,000, more particularly from 4,000 to 15,000. The hole-transporting or light emitting polymer network generally comprises from 5 to 50, preferably from 10 to 30, monomeric units.

The polymer network may comprise a light emitting electroluminescent polymer, a hole transporting polymer, or an electron transporting polymer. This light emitting or charge transporting polymer may be used in a variety of devices including, but not limited to, electronic devices, light emitting devices, organic light emitting devices, lighting elements, organic field effect transistors, photovoltaics and lasers. In certain embodiments of the invention, the polymer network may be used as a host for phosphorescent emitters.

The process according to a fourth aspect of the invention, which provides for the preparation of a polymer according to the third aspect of the invention, comprises the polymerisation or crosslinking of a material comprising at least one reactive mesogen, typically via photopolymerisation or photocrosslinking of suitable end-groups of the at least one reactive mesogen.

A typical crosslinking or polymerisation process involves exposure of a reactive mesogen of general formula (III) to UV radiation to form either an excited state or an initial radical having at least one radicalised endgroup B. or B₁. which is capable of reacting with another B or B₁ endgroup.

Preferably, the endgroup B or B₁ is selected to be susceptible to photopolymerisation or photocrosslinking and the polymer is formed by photopolymerisation or photocrosslinking. The photopolymerisation or photocrosslinking may be performed substantially free, or preferably completely free, of photoinitiator. In preferred embodiments of the invention, the process results in crosslinking, e.g. to form a polymer network, preferably an insoluble, crosslinked network.

Suitable photopolymerisable endgroups include acrylates, methacrylates and nonconjugated 1,4, 1,5 and 1,6 dienes. Suitable photocrosslinkable endgroups include coumarins and cinnamates, including derivatives of 6- or 7-hydroxycoumarins, as described by M O'Neill and S M Kelly, J. Phys. D. Appl. Phys. (2000), 33, R67.

In those embodiments wherein the endgroups are dienes, the reaction typically involves cyclopolymerisation by means of a sequential intramolecular and intermolecular propagation, wherein a ring structure is formed first by reaction of the free radical with the second double bond of the diene group. A double ring is then obtained by the cyclopolymerisation, thereby providing a particularly rigid backbone. The reaction is, in general, sterically controlled. In preferred aspects of the invention, the polymerisation process results in crosslinking to form a polymer network, typically an insoluble, crosslinked network.

In certain aspects of the invention, the photopolymerisation or photocrosslinking process may be conducted at room temperature, thereby minimising any possible thermal degradation of the reaction mesogen or polymer entities. Photopolymerisation is preferable to thermal polymerisation because it allows subsequent sub-pixellation of the formed polymer by lithographic means.

Further steps may be conducted subsequent to the polymerisation process, for example the polymer may be doped with e.g. photoactive dyes.

The hole-transporting polymer network is typically a liquid crystal which can be aligned to emit polarised light. Suitable polymers may be based on the central divalent carbocyclic (aromatic or alicyclic) or heterocyclic ring structures M which are detailed above, including, for example, fluorene or thiophene systems.

The process according to the sixth aspect of the invention for applying a light emitting polymer to a surface comprises applying a material according to the second aspect of the invention to said surface and photopolymerising or photocrosslinking said material in situ to form a light emitting polymer. Preferably, said material is applied to said surface by means of a spin-coating technique.

In preferred embodiments of the invention, said surface comprises a photoalignment layer. The photoalignment layer typically comprises a chromophore attached to a sidechain polymer backbone by a flexible spacer entity. Suitable chromophores include cinnamates or coumarins, including derivatives of 6 or 7-hydroxycoumarins. Suitable flexible spacers comprise unsaturated organic chains, including, for example, aliphatic, amine or ether linkages.

Exemplary photoalignment layers comprise, for example, 7-hydroxycoumarin compounds. Other suitable materials for use in photoalignment layers are described in M. O'Neill and S. M. Kelly, J. Phys. D. Appl. Phys. (2000), 33, R67.

In certain aspects of the invention, the photoalignment layer is photocurable. This allows for flexibility in the angle in the azimuthal plane at which the light emitting polymer (e.g. as a liquid crystal) is alignable and, thus, flexibility in its polarisation characteristics. The photalignment layer may also be doped with a hole-transport compound, i.e. a compound which enables transport of holes within the photoalignment layer, such as a triarylamine. Examples of suitable triarylamines include those described in C. H. Chen, J. Shi, C. W. Tang, Macromol Symp. (1997) 125, 1. An exemplary hole transport compound is 4,4′,4″-tris[N-(1-napthyl)-N-phenylamino]triphenylamine.

Optionally, the hole-transport compound has a tetrahedral (pyramidal) shape which acts so as to controllably disrupt the alignment characteristics of the layer. In one embodiment, the photoalignment layer includes a copolymer incorporating both linear rod-like hole-transporting and photoactive side chains.

The hole-transporting or light emitting polymer network is aligned on the photoalignment layer. Suitably, the photoaligned polymer comprises uniaxially aligned chromophores. Typically polarization ratios of 30 to 40 are required, but with the use of a clean up polarizer ratios of 10 or more can be adequate for display uses.

The hole-transporting or light emitting polymer network may be aligned by a range of methods including mechanical stretching, rubbing, and Langmuir-Blodgett deposition. Mechanical alignment methods can however lead to structural degradation. The use of rubbed polyimide is a suitable method for aligning the light emitting polymer, especially in the liquid crystal state. However, standard polyimide alignment layers are insulators, giving rise to low charge injection for OLEDs.

The susceptibility to damage of the alignment layer during the alignment process can be reduced by the use of a non-contact photoalignment method. In such methods, illumination with polarized light introduces a surface anisotropy to the alignment layer and hence a preferred in-plane orientation to the overlying light emitting polymer (e.g. in liquid crystal form). M. O'Neill, S. M. Kelly, J. Appl. Phys. D (2000) 33, R67, provides a review of photalignment materials and methods.

In preferred embodiments of the invention, the aligned hole-transporting or light emitting polymer network is in the form of an insoluble nematic polymer network. Crosslinking has been found to improve the photoluminescence properties.

The device according to the fifth aspect of the invention may optionally comprise additional layers such as carrier transport layers. The presence of an electron-transporting polymer layer, for example comprising an oxadiazole ring-containing compound, has been found to increase electroluminescence.

Subsequent pixelation of the light emitter may be achieved by selective photopatterning to produce red, green and blue pixels as desired. The pixels are typically rectangular in shape. The pixels typically have a size of from 1 to 50 μm. For microdisplays the pixel size is likely to be from 1 to 50 μm, preferably from 5 to 15 μm, more preferably from 8 to 10 μm. For other displays, larger pixel sizes, e.g. 300 μm, are more suitable.

In one preferred aspect, the pixels are arranged for polarized emission. Suitably, the pixels are of the same colour but have their polarization direction in different orientations. To the naked eye this would appear as one colour but, when viewed through a polarizer, some pixels would be bright and others less bright, thereby giving an impression of 3D viewing when viewed with glasses having a different polarization for each eye.

The layers may also be doped with photoactive dyes which may comprise dichroic or pleochroic dyes, or phosphorescent emitters. Examples include anthraquinone dyes, tetralines or rare earth emitters, such as organometallic chromophores incorporating indium and europium, including those described in S. M. Kelly, Flat Panel Displays: Advanced Organic Materials, RSC Materials Monograph, Ed. J. A. Connor, (2000). Different dopant types can be used to obtain different pixel colours.

Pixel colour can also be influenced by the choice of chromophore, with different chromophores having more suitability as red, green or blue pixels, for example using suitably modified anthraquinone dyes.

Multicolour emitters are also envisaged within the scope of the present invention, said emitters comprising arrangements or sequences of different pixel colours. Thus, for example, a suitable multicolour emitter comprises stripes of red, green and blue pixels having the same polarization state. This may be used as a sequential colour backlight for a display which allows the sequential flashing of red, green and blue lights. Such backlights can be used in transmissive and reflective FLC displays where the FLC acts as a shutter for the flashing coloured lights.

A further suitable multicolour emitter comprises a full colour pixelated display in which the component pixels thereof have the same or different alignment. Suitable multicolour emitters may be formed by a sequential coat, selective cure, wash off process in which a first colour emitter is applied to the aligned layer by a suitable coating process (e.g. spin coating). The coated first colour emitter is then selectively cured only where pixels of that colour are required. The residue (of uncured first colour emitter) is then washed off. A second colour emitter is subsequently applied to the aligned layer, cured only where pixels of that colour are required, and the residue is washed off. If desired, a third colour may be applied by repeating the process for the third colour. This process may be used to form a pixelated display such as for use in a colour emissive display, and is simpler than traditional printing (e.g. ink jet) methods of forming such displays.

The invention also envisages a backlight for a display comprising a power input and a hole-transporting or light emitting polymer network. The backlight may be arranged for use with a liquid crystal display. Optionally, the backlight may be monochrome or multicolour. The invention also provides a display comprising a screen and a hole-transporting or light emitting polymer network or backlight as hereinbefore described. The screen may have any suitable shape or configuration, including flat or curved, and may comprise any suitable material, such as glass or a plastic polymer. The hole-transporting and light emitting polymer networks of the present invention have been found to be particularly suitable for use with screens comprising plastic polymers such as polyethylene or polyethylene terephthalate (PET).

The display is suitable for use in consumer electronic goods such as mobile telephones, hand-held computers, watches and clocks and games machines. There is also envisaged a security viewer, e.g. in kit form, which comprises a charge transporting or light emitting polymer network according to the invention wherein the pixels are arranged for polarized emission, and view glasses having a different polarization for each eye.

The method according to the sixth aspect of the invention also envisages a method of forming a light emitter for a display which comprises forming a photoalignment layer and aligning a light emitting polymer on said photoalignment layer. Alternatively, there is provided a method of forming a light emitter for a display comprising forming a photoalignment layer, aligning a reactive mesogen on said photoalignment layer, and forming a hole-transporting or light emitting polymer network by photopolymerisation or photocrosslinking of said reactive mesogen.

The invention also provides a method of forming a multicolour emitter comprising applying a first colour light emitting polymer to the photoalignment layer, selectively curing said first colour light emitter only where that colour is required, washing off any residue of uncured first colour emitter, and repeating the process for a second and any subsequent light colour emitters.

The structures disclosed herein offer distinct advantages over the prior art materials in terms of the standard of performance at certain energy levels. Thus, it is found that the materials have lower transition temperatures as a consequence of the presence of the bulky carbazole groups. Furthermore, the bulky central (M) groups inhibit aggregation and so avoid the quenching of luminescence and, additionally, the new compounds are typically liquid crystalline materials having lower melting points and very good uniform film-forming properties. They also provide good charge transport properties in view of the short intermolecular distances involved.

The reactive mesogens according to the present invention are found to be particularly suitable for use as hosts for organometallic phosphorescent dopants for highly efficient OLEDs, especially for lighting applications.

The reactive mesogens according to the present invention may be synthesised from readily available starting materials by synthetic techniques which are well known to those skilled in the art. Thus, condensation reactions between suitable carbocyclic or heterocyclic core linking materials and carbazole compounds having labile groups such as halogen groups may conveniently be employed. The synthesis techniques which are employed are non-catalysed, thereby providing significant advantages in terms of the absence of metal impurities and other contaminants, and the shorter synthetic pathways involved also facilitate lower cost synthesis.

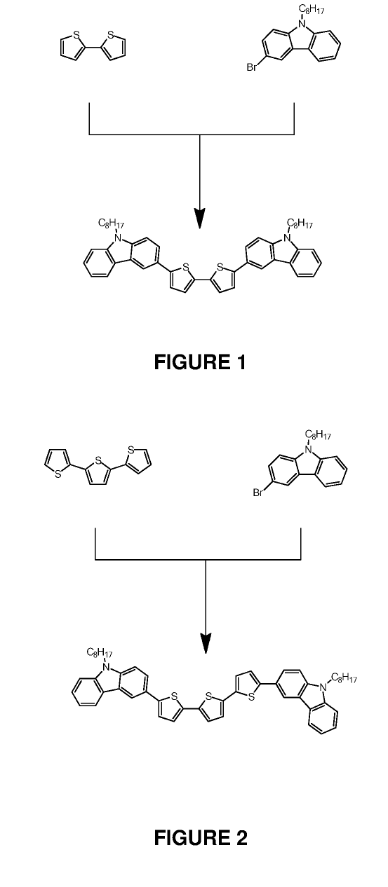

Synthesis of compounds according to the invention will now be described with reference to the accompanying Figures, wherein there are illustrated reaction schemes for the synthesis of five different reactive mesogens according to the invention. Thus, in FIG. 1 there is shown the synthesis of an asymmetric reactive mesogen prepared by reacting bithiophene with 3-bromo-9-octylcarbazole to give bis-3-(9-octylcarbazolyl)bisthiophene.

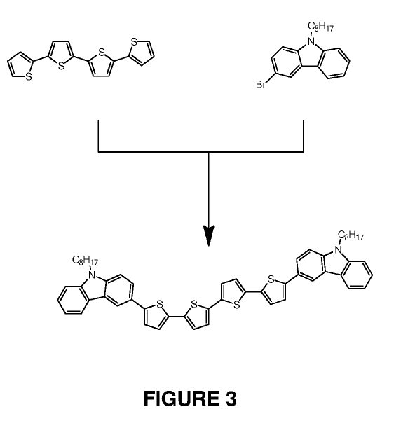

Turning now to FIG. 2, a further reactive mesogen is prepared from the condensation of a trithiophene derivative with 3-bromo-9-octylcarbazole, whilst FIG. 3 shows a still further reactive mesogen obtained from the condensation of a tetrathiophene compound with 3-bromo-9-octylcarbazole.

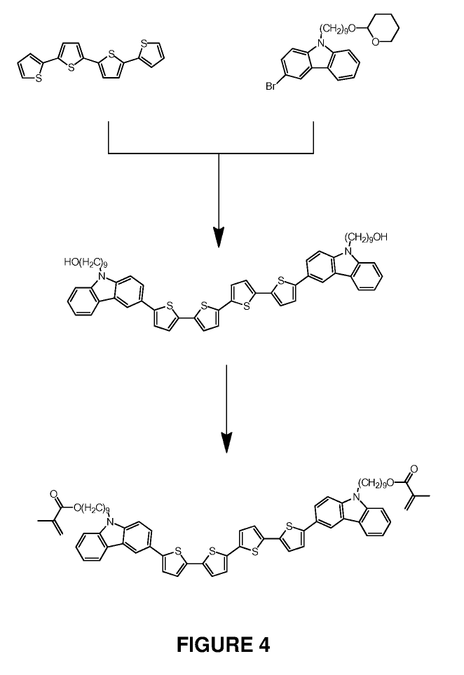

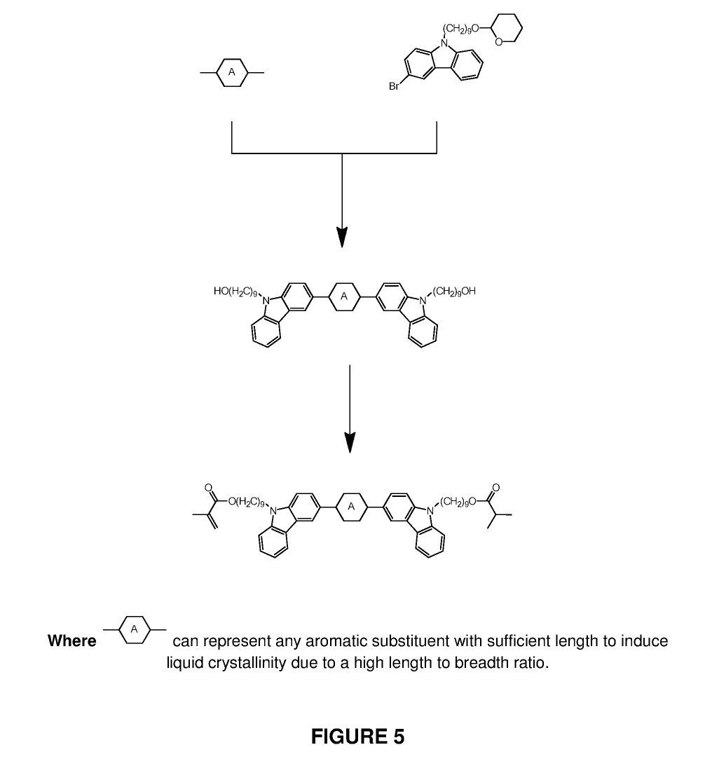

In FIG. 4, there is illustrated the preparation of a yet further reactive mesogen from the condensation of a tetrathiphene with 3-bromo-9-(2-tetrahydropyranyl)oxynonylcarbazole to form a bis(9-(hydroxynonyl)-3-carbazolyl tetrathiophene derivative, which is then converted to the final product, whilst FIG. 5 schematically depicts the formation of a further reactive mesogen from the condensation of an aromatic liquid crystalline compound with 3-bromo-9-(2-tetrahydropyranyl)oxynonylcarbazole to form the bis(9-(hydroxynonyl)-3-carbazolyl derivative of the aromatic compound, which is then converted to the corresponding bis(9-(methacryloyloxynonyl)-3-carbazolyl derivative.

Specific embodiments of the invention will now be illustrated, without in any way limiting the scope of the invention, by reference to various materials which are typical of those falling within the scope of the present invention. Thus, the compounds (III-A)-(III-F) have been prepared and characterised:

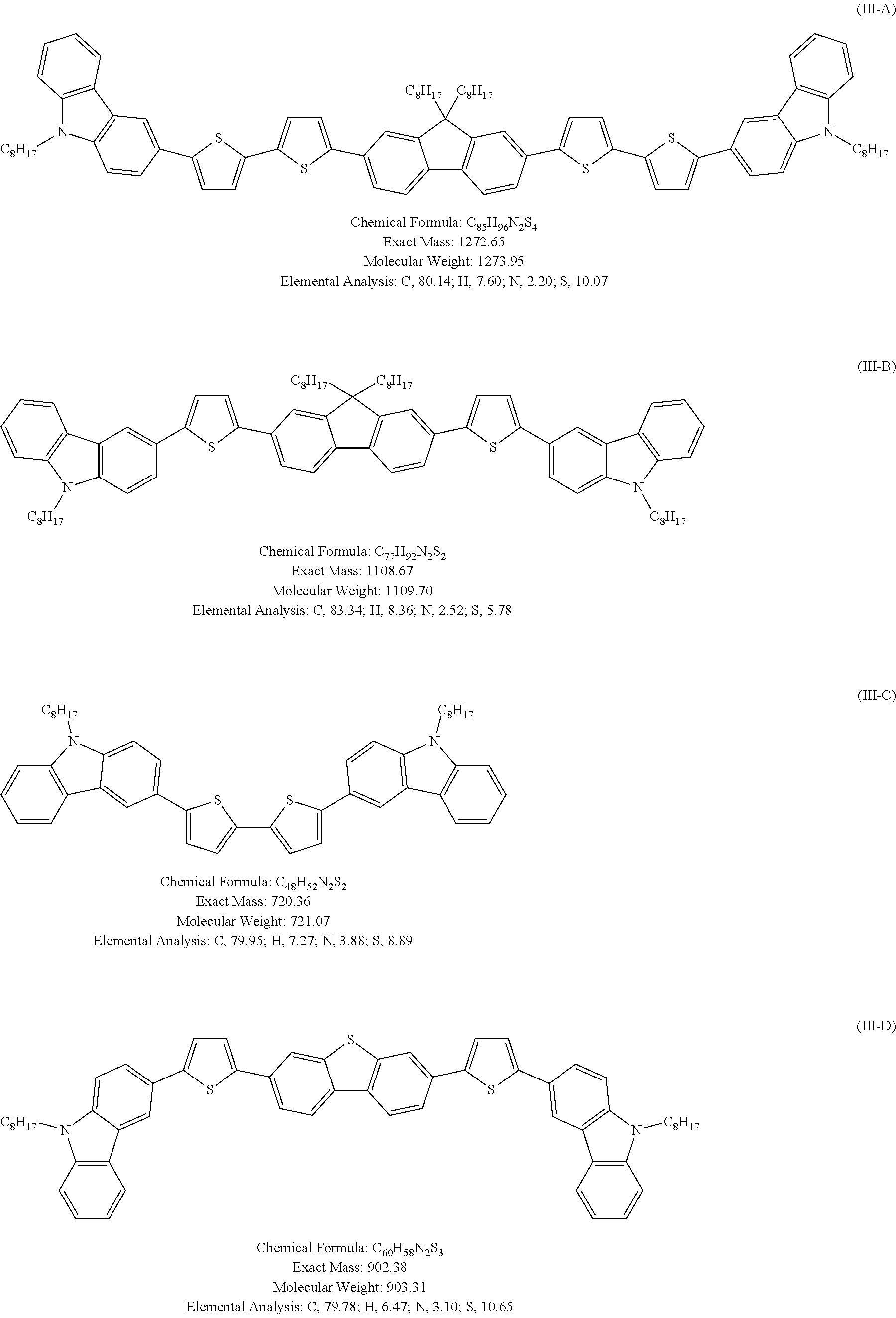

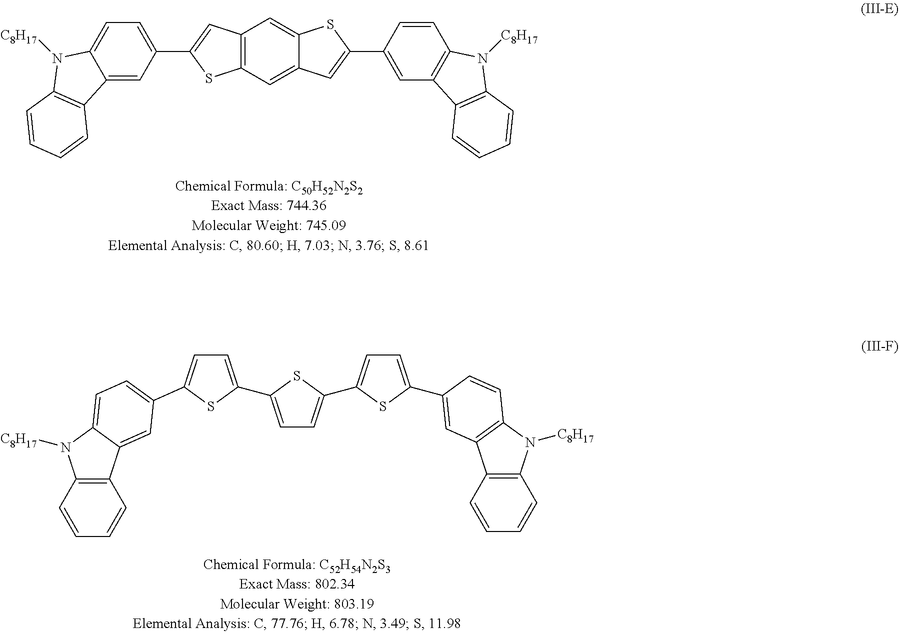

The compounds (III-A)-(III-F) are typical examples of compounds according to the invention which are capable of utilising the presence of carbazole moieties at the extremity of the structure to provide the correct energy levels required as hole-transport materials. The compounds also possess liquid crystallinity whilst still being polymerisable and having the required physical properties.

Testing has been carried out for compounds (IIIA)-(IIID) using Cyclic Voltametry (CV) and all four compounds have shown an increase in the Highest Occupied Molecular Orbital (HOMO) level. This shows that the properties of the materials are in the region that is required for all hole-transport materials. Compound (III-C) has also been tested as a thin-film and has a HOMO level of −5.2 eV. If this performance were to be replicated on substrates other than glassy carbon, the compound would be eminently suitable as a hole-transport material in thin films.

On the basis of the performance so far observed, it appears that these compounds will facilitate fine-tuning of properties such as absorbance, energy levels and mobility of the materials, thereby allowing for the preparation of bespoke materials for specific needs.

Further compounds (IIIG)-(IIIJ) have also been synthesised, wherein a fluorene or thiofluorene moiety comprises the divalent core linking group:

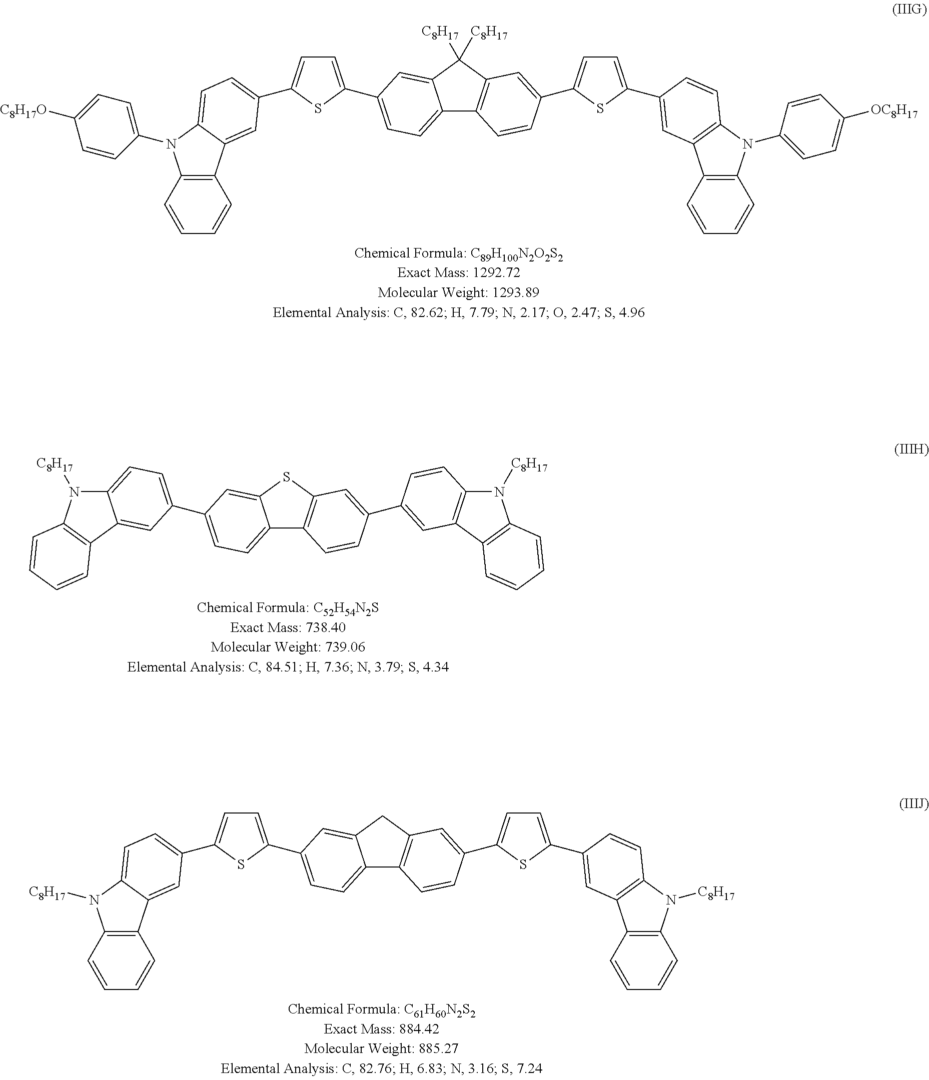

In addition, compounds (IIIK) and (IIIL) have been prepared, these compounds comprising a divalent benzothiadiazole core material:

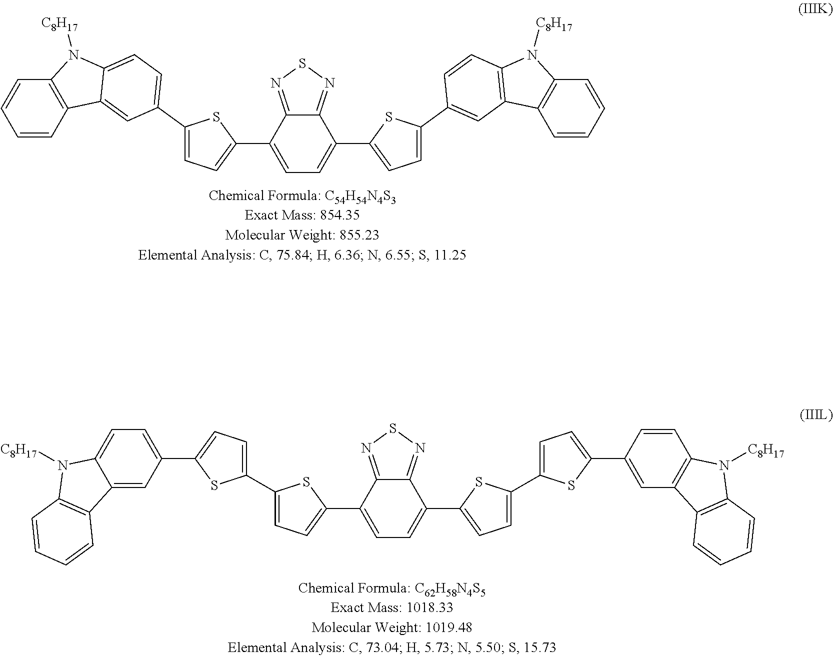

The incorporation on these compounds of a benzothiadiazole moiety, which is more associated with electron-transfer than hole-transfer. However when incorporated with carbazole moieties, the compound will provide a low-band gap material that will give a variation of properties to the other materials depicted. This again helps to facilitate tailoring of materials to the known efficient phosphorescent emitters, thereby allowing a guest-host mixture to be obtained that can provide an efficient white PHOLED, wherein the triplet energy levels can be varied so that they match those of heavy metal phosphorescent emitters.

A further advantage of the present approach is that it allows for the production of larger quantities of the disclosed materials than is possible with the materials of the prior art. This is a consequence of the relatively straightforward and improved method of synthesis, which also allow for the production of materials within a shorter time frame.

Further examples of materials according to the invention may be gleaned from Table 1 below, which shows the structures which have been prepared and the physical data relating to these examples.

TABLE 1
REACTIVE MESOGENS

| | | CV Data | Transition |
|---|---|---|---|
| Name | Structure | eV | Temperature |
| (III-A) | 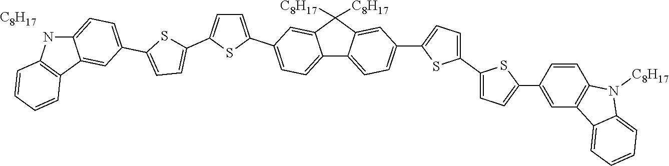 | HOMO: 5.37 | Tg. 18 Cr. 107 N. 143 I |
| (III-B) | 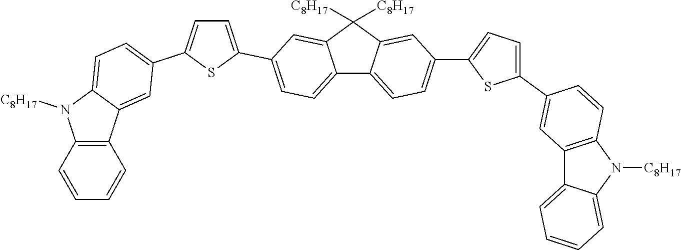 | HOMO: 5.40 | Tg. 19 Mp. 158 |
| (III-C) | 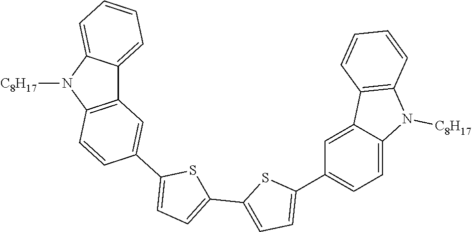 | HOMO: 5.30 | Tg. 64 Mp. 168 |
| (III-D) | 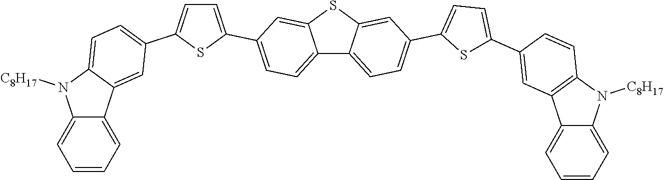 | HOMO: 5.70 | Tg. 39 Mp. 189 |
| (III-E) | 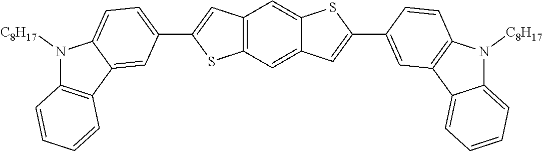 | HOMO: 5.41 | Tg. 76 Mp. 190 |
| (III-F) | 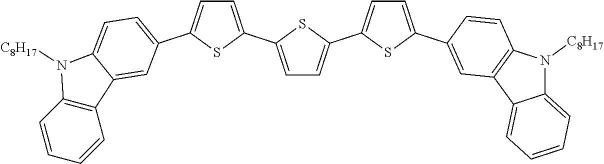 | HOMO: 5.28 | Mp. 166 |
| (III-K) | 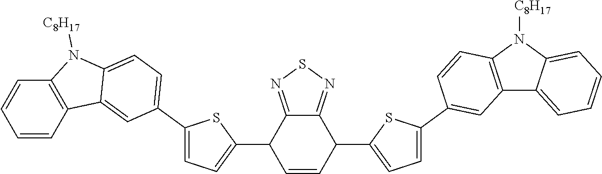 | HOMO: 5.31 LUMO: 3.55 | Tg. 56 Mp. 307 |
| (III-M) | 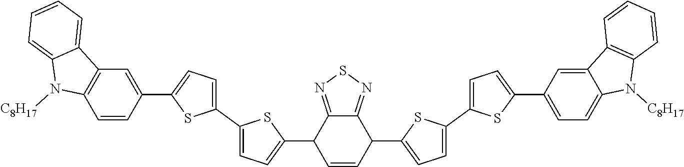 | HOMO: 5.33 LUMO: 3.57 | Tg. 74 Mp. 343 |
| (III-N) | 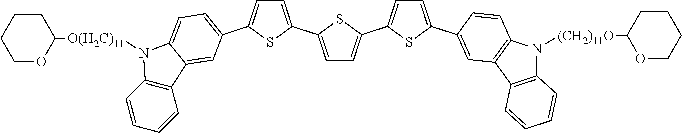 | HOMO: | |
| (III-O) | 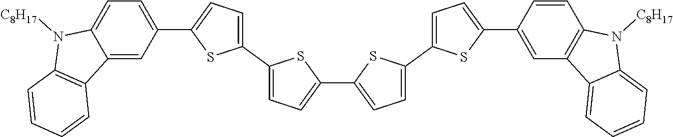 | HOMO: 5.27 | Mp. 162 |
| (III-P) | 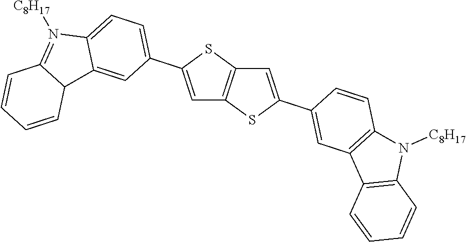 | HOMO: 5.31 | Tg. 46 Mp. 187 |
| (III-R) | 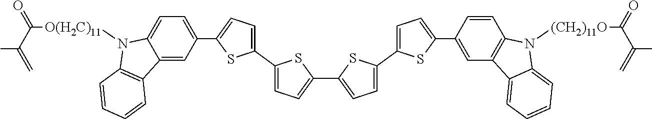 | HOMO: LUMO: | Cr. 164 Sm. 178 |
| (III-S) | 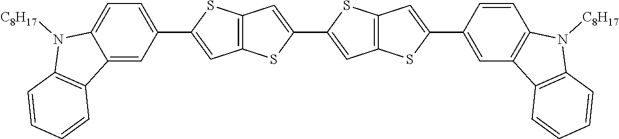 | HOMO: 5.31 LUMO: | Mp. |
| (III-T) | 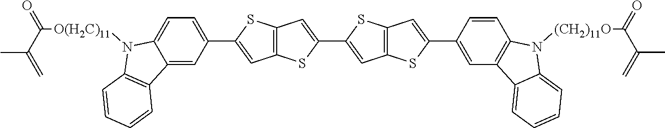 | HOMO: LUMO: | |
| (III-U) | 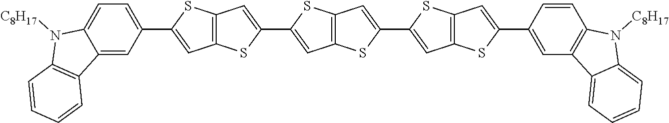 | HOMO: 5.27 LUMO: | |
| (III-V) | 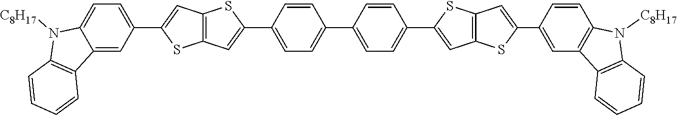 | HOMO: 5.40 LUMO: | Cr. 183 Sm. 227 I. |
| (III-W) | 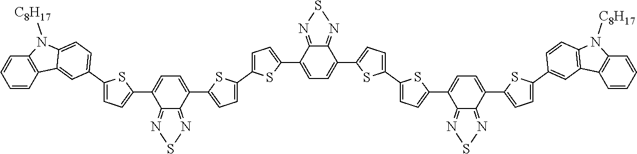 | HOMO: 5.21 LUMO: 3.57 | |
| (III-X) | 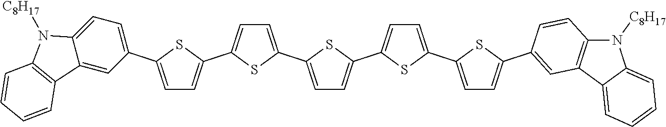 | HOMO: LUMO: | |
| (III-Y) | 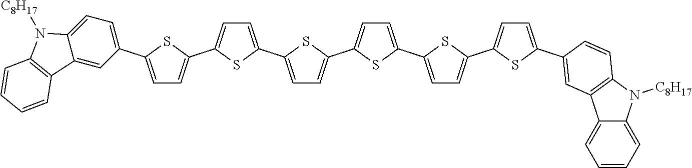 | HOMO: LUMO: | |

Key to Table:
Tg = Glass Transition Temperature (° C.)
Mp = Melting Point (° C.)
HOMO = Highest Occupied Molecular Orbital
LUMO = Lowest Unoccupied Molecular Orbital
Cr = Crystal (° C.)
Sm = Smectic (° C.)
I = Isotopic
N = Nematic

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments.

The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

1. A photopolymerisable or photocrosslinkable reactive mesogen for forming a hole-transporting or light emitting polymer network, said mesogen having the structure (III):
(B₁-S₁-A₁)ₙ-M-(A₂-S₂-B₂)ₘ (III)
wherein:
M is a chromophoric aromatic or heterocyclic moiety;
A₁ and A₂ are carbazole groups substituted in the 3-position of the carbazole ring, and may be the same or different;
S1 and S2 are spacers, and may be the same or different;
B1 and B2 are polymerisable groups, and may be the same or different; and m and n are independently integers from 1 to 10.

2. A photopolymerisable or photocrosslinkable reactive mesogen as claimed in claim 1 wherein polymerisable groups B1 and B2 are attached via the spacer groups to the nitrogen atom of the carbazole group.

3. A photopolymerisable or photocrosslinkable reactive mesogen as claimed in claim 1 wherein B1 and B2 are photopolymerisable or photocrosslinkable groups.

4. A photopolymerisable or photocrosslinkable reactive mesogen as claimed in claim 1 wherein M is an aromatic or heterocyclic moiety having sufficient length to provide liquid crystallinity in view of a high length to breadth ratio.

5. A photopolymerisable or photocrosslinkable reactive mesogen as claimed in claim 4 wherein M is a chromophoric aromatic or heterocyclic moiety comprising at least four aromatic, fused aromatic or heterocyclic rings.

6. A photopolymerisable or photocrosslinkable reactive mesogen as claimed in claim 1 wherein m and n independently have values of from 1 to 3.

7. A material for forming a light emitting or charge transporting polymer network, said material comprising a photopolymerisable or photocrosslinkable reactive mesogen as claimed in claim 1.

8. A material as claimed in claim 7 which comprises at least one additional photopolymerisable or photocrosslinkable reactive mesogen.

9. A material as claimed in claim 8 wherein said at least one additional photopolymerisable or photocrosslinkable reactive mesogen has the formula (1):
B-S-A-S-B (I)
wherein:
A is a chromophore;
S is a spacer; and
B is an endgroup which is susceptible to photopolymerisation or photocrosslinking.

10. A charge transporting or light emitting polymer network which is obtained by polymerisation or crosslinking of the material of claim 7.

11. A charge transporting or light emitting polymer network as claimed in claim 10 having a molecular weight of above 4,000.

12. A process for the preparation of the polymer network of claim 10, said process comprising the polymerisation or crosslinking of said material comprising at least one reactive mesogen via photopolymerisation or photocrosslinking of photopolymerisable or photocrosslinkable end-groups of the at least one mesogen.

13. A process as claimed in claim 12 for forming a charge transporting or light emitting polymer network comprising photopolymerisation or photocrosslinking of a composition
comprising at least one reactive mesogen having the formula (III):
(B₁-S₁-A₁)ₙ-M-(A₂-S₂-B₂)ₘ (III)
wherein
M is a chromophoric aromatic or heterocyclic moiety;
A₁ and A₂ are carbazole groups substituted in the 3-position of the carbazole ring, and may be the same or different;
S1 and S2 are spacers, and may be the same or different;
B₁ and B2 are polymerisable groups, and may be the same or different; and m and n are independently integers from 1 to 10,
wherein said process provides a hole-transporting or light emitting polymer network.

14. A process as claimed in claim 13 wherein said process comprises the preparation of a polymer network from said at least one reactive mesogen and at least one additional photopolymerisable or photocrosslinkable mesogen.

15. A process as claimed in claim 14 wherein said at least one additional photopolymerisable or photocrosslinkable reactive mesogen has the formula (I):
B-S-A-S-B (I)
wherein:
A is a chromophore;
S is a spacer; and
B is an endgroup which is susceptible to photopolymerisation or photocrosslinking.

16. A process as claimed in claim 12 wherein said at least one reactive mesogen has a molecular weight of from 400 to 2,000.

17. A process for applying a charge transporting or light emitting polymer network to a surface, said process comprising applying a material as claimed in claim 7 to said surface and photopolymerising or photocrosslinking said material in situ to form a charge transporting or light emitting polymer network.

18. A process as claimed in claim 17 wherein said material is applied to said surface from solution by means of a spin-coating technique.

19. A process as claimed in claim 17 wherein said surface comprises a photoalignment layer.

20. (canceled)

21. A backlight or display comprising a charge transporting or light emitting polymer network as claimed in claim 10.

22. A mobile telephone, hand-held computer, watch, clock, games machine or security viewer comprising a display as claimed in claim 21.

23. (canceled)

24. (canceled)

25. (canceled)

26. (canceled)

27. (canceled)

28. (canceled)

29. (canceled)

30. (canceled)
